(19) United States
(12) Patent Application Publication
(10) Pub. No.: US 2025/0309183 A1
(43) Pub. Date: Oct. 2, 2025

(54) MOUNTING DEVICE

(71) Applicant: SAMSUNG ELECTRONICS CO., LTD., Suwon-si (KR)

(72) Inventors: Fumitaka MOROISHI, Suwon-si (KR); Masato KAJINAMI, Suwon-si (KR)

(21) Appl. No.: 19/053,179

(22) Filed: Feb. 13, 2025

(30) Foreign Application Priority Data
Mar. 27, 2024 (JP) 2024-051153

(51) Int. Cl. H01L 23/00

(52) U.S. Cl. CPC H01L 24/75; H01L 2224/75725; H01L 2224/75753; H01L 2224/75802; H01L 2224/75824; H01L 2924/40

(57) ABSTRACT

A bonding head according to some embodiments of the present disclosure may include: a double-acting air bearing cylinder configured to move a cylinder rod in a vertical direction; a first scale on a same axis as the cylinder rod and having a first encoder pattern; a first encoder sensor configured to decipher a position of the first encoder pattern; a second scale on the same axis as the cylinder rod and having a second encoder pattern; a second encoder sensor configured to decipher a position of the second encoder pattern; a shaft motor on the same axis as the cylinder rod and configured to move the cylinder rod in the vertical direction based on a deciphering result of the first encoder sensor, and a piezo motor on the same axis as the cylinder rod and configured to move the cylinder rod in a rotation direction.

### CROSS-REFERENCE TO RELATED APPLICATION

This application claims priority to and the benefit of Japanese Patent Application No. 2024-051153, filed on Mar. 27, 2024, the contents of which are incorporated herein by reference in their entirety.

### FIELD

The present disclosure relates to a mounting device.

### BACKGROUND

To achieve low power consumption and high operating speed, multi-layering of semiconductor devices is in progress, and the chip bonding process, which may be a stacking process of CoC (Chip on Chip), CoW (Chip on Wafer) semiconductor chips or a mounting process of semiconductor packages, is changing from the connection method between contacts by conventional wire bonding to a connection method by flip chip or silicon through via (TSV) that may achieve more space saving.

However, the bonding precision of several tens of μm is sufficient in the connection method between contacts by wire bonding. In contrast, in the connection methods such as by flip chips, sub-μm precision is required as mounting precision in order to reduce the influence of misalignment of bump positions due to angle errors while improving mounting and productivity under high loads due to miniaturization or high density of bumps and enlargement of chip size. Accordingly, position control in the rotation direction of the bonding head becomes important in addition to position control in the vertical direction.

In addition, with flip-chip mounting bonded members such as wafers, semiconductor chips, and interposers, high precision image processing for the position control also becomes important. However, the depth of field becomes shallow when high magnification is attempted to increase the pixel resolution of the image so high-precision position control in the vertical direction is also required.

The following patent document 1 discloses a pressurizing device for controlling pressurization of a pressurized body by an applied pressure to the pressurized body, such as a chip or a substrate. The following patent document 2 discloses a hydraulic actuator for enabling position control in the rotation direction in addition to the vertical direction as the position control of the rod.
[Patent Document 1] Japanese Patent Laid-Open Publication Number 2010-64127
[Patent Document 2] Japanese Patent Laid-Open Publication Number 2015-113868

The device according to Patent Document 1 may control the position and load control in the vertical direction, but may not control the rotation direction, so mounting precision may not be secured. The device according to Patent Document 2 performs rotation control to adjust the bonding position, but the rotation axis and the axis of the rod are not arranged on the same axis but instead are spaced apart from each other, making it difficult to control the rotation position with high precision.

### SUMMARY

The present disclosure provides a mounting device for position-controlling a vertical direction and a rotation direction of a cylinder rod for maintaining bonded members such as a chip or a substrate with high precision.

The task may be achieved by one of (1) to (7).

(1) A mounting device including a bonding head and a bonding stage.

The bonding head may include: a double-acting air bearing cylinder having a cylinder rod extending in a vertical direction and configured to move the cylinder rod in the vertical direction by a first vertical moving amount,
a first scale arranged on the same axis as the cylinder rod to allow an operational range of the cylinder rod in the rotation direction and having a first encoder pattern including a pattern sequence for detecting the position of the cylinder rod in the vertical direction,
a first encoder sensor facing the first scale and configured to decipher a position of the first encoder pattern,
a second scale arranged on the same axis as the cylinder rod to allow the operational range of the cylinder rod in the vertical direction and having a second encoder pattern including a pattern sequence for detecting the position of the cylinder rod in the rotation direction,
a second encoder sensor facing the second scale and configured to decipher a position of the second encoder pattern,
a shaft motor arranged on the same axis as the cylinder rod, and configured to move the position of the cylinder rod in the vertical direction by a second vertical moving amount when correcting a vertical position so that the position of the cylinder rod in the vertical direction becomes a target vertical position based on a deciphering result of the first encoder sensor, and/or
a piezo motor configured to move the cylinder rod in the rotation direction by a rotation moving amount so that the rotation position of the cylinder rod becomes a target rotation position based on a deciphering result of the second encoder sensor.

(2) The second scale may be at a lower portion of the cylinder rod of the double-acting air bearing cylinder in the mounting device of (1).

(3) The double-acting air bearing cylinder may be below the shaft motor in the mounting device of (1) or (2).

(4) The mounting device may include: a ball spline including a spline shaft, a spline nut, and an angular bearing including an outer race ring fixed to a housing of the bonding head and an inner ring race ring fixed to the spline nut, and arranged above the shaft motor and configured to transmit a driving force of the piezo motor, a flexible coupler connecting a lower portion of the spline shaft and an upper portion of a magnet rod of the shaft motor in a synchronously rotatable manner, a rigid coupler connecting a lower portion of the magnet rod of the shaft motor and an upper portion of the cylinder rod of the double-acting air bearing cylinder in a synchronously rotatable manner, and a rotor fixed to the spline nut, and configured to convert the driving force of the piezo motor into a torque and transmit the same to the spline nut in the mounting device of one of (1) to (3).

(5) The second encoder sensor may include a plurality of second encoder sensors that may be arranged around the second scale, and may be configured to detect position misalignment of a rod end of the double-acting air bearing cylinder in the horizontal direction in the mounting device of one of (1) to (4).

(6) The double-acting air bearing cylinder may include a servo valve configured to adjust inflow/outflow amounts of air to/from the cylinder so that the cylinder rod moves by the first vertical moving amount in the mounting device of one of (1) to (5).

(7) The mounting device may include a control device including: a calculator for configured to calculate an average thrust value of the shaft motor, an obtaining module configured to obtain a driving state of the shaft motor, a determining module configured to compare the average thrust value calculated by the calculator and a predetermined threshold value to determine whether the average thrust value exceeds the threshold value, and a driving controller configured to adjust opening of the servo valve of the double-acting air bearing cylinder so that a load of the shaft motor does not exceed an allowable value based on a determination result of the determining module in the mounting device of one of (1) to (6).

The mounting device according to some embodiments of the present disclosure may position-control the vertical direction and the rotation direction of the cylinder rod for maintaining the shaft motor and the bonded member such as a chip or a substrate with high precision.

### BRIEF DESCRIPTION OF THE DRAWINGS

FIG. 1 shows a schematic diagram of a mounting device according to some embodiments.

FIG. 2 shows a schematic diagram of a bonding head.

FIG. 3A shows a schematic diagram of a first scale.

FIG. 3B shows a schematic diagram of a second scale.

FIG. 4A shows an arrangement of a second encoder sensor for a second scale of a second position detector.

FIG. 4B shows another arrangement of a second encoder sensor for a second scale of a second position detector.

FIG. 5 shows an arrangement of a piezo motor.

FIG. 6 shows a function block diagram of a mounting device.

FIG. 7 shows a flowchart on a process for bonding a mounting device.

FIG. 8 shows a flowchart on position control of a cylinder rod in a vertical direction.

FIG. 9 shows a flowchart on position control of a cylinder rod in a rotation direction.

FIG. 10 shows a flowchart on process control of a servo valve.

### DETAILED DESCRIPTION

Hereinafter, example embodiments of the present disclosure will be described in detail with reference to the attached drawings. In the drawings below, identical reference numerals represent identical components, and the sizes of each component in the drawings may be expressed at a different scale than in reality for clarity and convenience of description. The embodiments described below are merely examples, and various modifications are possible from such embodiments.

The part described as “upper” or “above” may include not only the part directly above in contact, but also the part above in non-contact. The part described as “below” or “beneath” may include not only the part directly below in contact, but also the part below in non-contact.

A component expressed in the singular includes plural components unless the context clearly indicates otherwise. When a part is said to “comprise” or “include” or “have” a component, this does not exclude other components, unless otherwise specifically stated, but rather may include other components.

For the steps that constitute a method, the order may be explicitly stated, or, if there is no contrary statement, the steps are executed in the appropriate order. It is not necessarily limited to the order in which the steps are described. Any use of example terms (e.g., etc.) is intended merely to illustrate technical ideas and is not intended to limit the scope of the patent claims, unless otherwise limited by such example terms.

In the explanations below, when describing with ordinal numerals such as “first” and “second,” unless specifically stated otherwise, they are used for convenience and do not specify any order.

A mounting device 1 according to some embodiments will now be described.

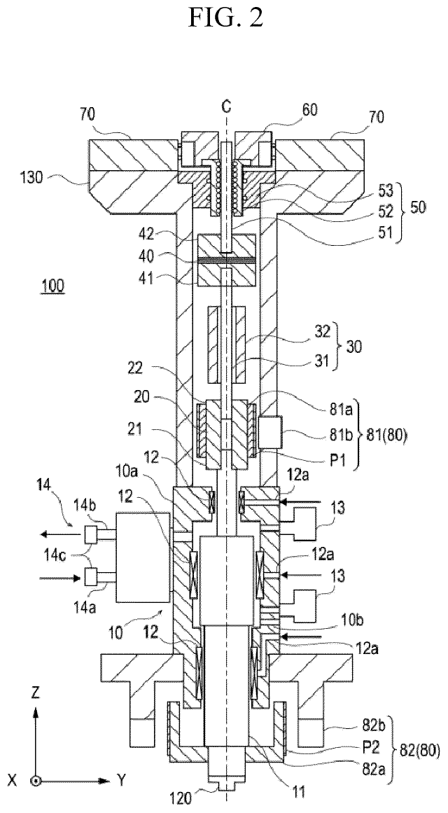

For better understanding and ease of description, an XYZ orthogonal coordinate system will be set to the mounting device 1. A direction parallel to an X-axis within a given plane is referred to as an X-axis direction. A direction parallel to a Y-axis that is perpendicular to the X-axis within a given plane is referred to as a Y-axis direction. A direction parallel to a Z-axis, which is orthogonal to each of the X-axis and the Y-axis, is referred to as a Z-axis direction. In the illustrated embodiment, a predetermined surface is parallel to a horizontal plane in the XY plane, and the Z-axis is a vertical direction that is orthogonal to the predetermined surface. The Z-axis coincides with the direction along a central axis C shown in FIG. 2. Up, down, left, and right directions in the description below and the configuration illustrated in each drawing are directions based on the assumption that the mounting device is installed on a horizontal surface in a normal installation state, and the up, down, left, and right directions in each drawing when viewed from the user are set as the up, down, left, and right directions.

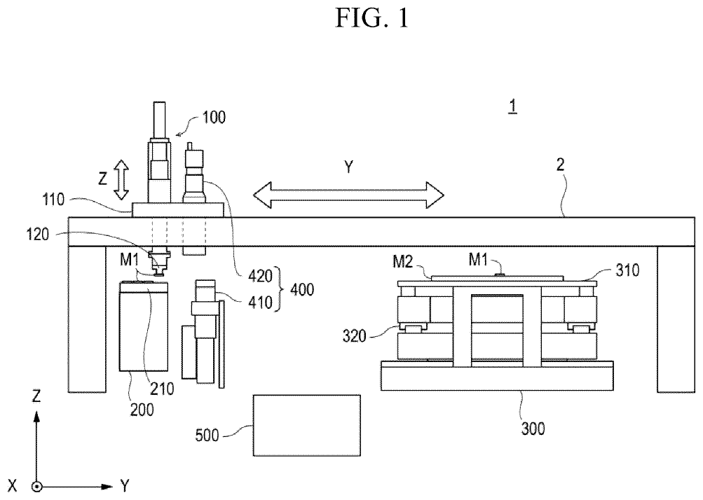

The mounting device 1 may include, as shown in FIG. 1, a bonding head 100 for maintaining a first junction member M1, a mounting table 200, a bonding stage 300, and an imaging device 400. The mounting device 1 may include a control device 500 for generally controlling driving of respective constituent elements of a device or various processes. The mounting device 1 may have components in addition to the respective constituent elements according to the executed processes.

The bonding head 100 may adsorb and maintain the first junction member M1 with a head 120 installed on a lower end of the cylinder rod 11. The first junction member M1 maintained by the head 120 may be mounted on a second junction member M2 such as a chip, a die, or an interposer.

The bonding head 100 may, as shown in FIG. 1, be mounted to be moveable in the Y-axis direction (or the right to left direction in the drawing) on a base 2 of the mounting device 1 by a driving device or driver 110 such as a linear motor. Accordingly, the bonding head 100 may move in the Y-axis direction between the mounting table 200 and the bonding stage 300.

The bonding head 100 may pick up the first junction member M1 mounted on the mounting table 200 with the head 120 and may move the same to the bonding stage 300 in the Y-axis direction. The bonding head 100 may bond the first junction member M1 to the second junction member M2 disposed on the bonding stage 300.

A configuration of the bonding head 100 will now be described. The bonding head 100 may, as shown in FIG. 2, include a double-acting air bearing cylinder 10, a rigid coupler 20, a shaft motor 30, a flexible coupler 40, a ball spline 50, a rotor 60, a piezo motor 70, and a position detector 80. Regarding the bonding head 100, the double-acting air bearing cylinder 10, the rigid coupler 20, the shaft motor 30, the flexible coupler 40, the ball spline 50, the rotor 60, and a first scale 81a and a second scale 82a of the position detector 80 may be arranged on the same axis (the center axis C in FIG. 2) as the cylinder rod 11 of the double-acting air bearing cylinder 10. The center axis C may be a center axis of the mounting device 1 and may also be a center axis of each of the components arranged on the same axis as the cylinder rod 11.

The double-acting air bearing cylinder 10 may include a cylinder rod 11, an air bearing 12, a pressure sensor 13, and a servo valve 14. The double-acting air bearing cylinder 10 may elevate and move the cylinder rod 11 in the Z-axis direction in the range of about 10 mm based on a first vertical moving amount by control of the controller 510 of the control device 500. Air with a predetermined pressure is taken into the double-acting air bearing cylinder 10 from a cylinder air-supply port 10b. The pressure in the housing 10a may be obtained by the pressure sensor 13.

The cylinder rod 11 may have a columnal or cylindrical shape extending in the Z-axis direction, may provide an air bearing 12 to a lower portion, an intermediate portion, and an upper portion, and may be mounted in the housing 10a. The cylinder rod 11 may be supported to elevate and move in the Z-axis direction and move in the rotation direction with respect to the Z-axis direction as a rotation axis by the air bearing 12. Air with a predetermined pressure may be supplied to the air bearing 12 from a supply portion (not shown) through an air bearing air supply port 12a.

The servo valve 14 may have an air supply portion or port 14a, an exhaust portion or port 14b, and a regulator 14c, and may adjust an opening degree of a valve of the air supply portion 14a or the exhaust portion 14b by use of the regulator 14c to elevate and move the cylinder rod 11 in the Z-axis direction by a first vertical moving amount. The servo valve 14 may make air flow into the upper portion of the cylinder rod 11 when descending the cylinder rod 11, and it may discharge the air in the housing 10a to an outdoor atmosphere from the upper portion of the cylinder rod 11 to reduce the pressure when ascending the cylinder rod 11.

The rigid coupler 20 may connect the upper portion (near the upper side end) of the cylinder rod 11 of the double-acting air bearing cylinder 10 and a lower portion (near the lower side end) of a magnet rod 31 of the shaft motor 30. As shown in FIG. 2, a first maintaining portion or lower portion 21 disposed on a lower side of the rigid coupler 20 may maintain the upper portion of the cylinder rod 11 (e.g., act as a stop), and a second maintaining portion or upper portion 22 disposed on an upper side may maintain a lower portion of the magnet rod 31. The cylinder rod 11 and the magnet rod 31 are connected by providing the rigid coupler 20 so efficient power delivery may be possible without backlash.

The shaft motor 30 may be configured with the magnet rod 31 where a magnet is inserted into a cylindrical shaft, and a coil 32 arranged to surround the magnet rod 31. The shaft motor 30 may be arranged so that the magnet rod 31 and the cylinder rod 11 may be on the same axis on the upper side of the double-acting air bearing cylinder 10 in the Z-axis direction. The shaft motor 30 may, under the control of the controller 510, perform a minute or fine position control in the Z-axis direction with a second vertical moving amount, which is an adjustment amount from the first vertical moving amount, when correcting the vertical position so that the descending position of the cylinder rod 11 may become a target vertical position.

The shaft motor 30 may adjust the position of the cylinder rod 11 by a small amount with the second vertical moving amount so that adjustment of the imaging device 400 may also be performed. Accordingly, when alignment marks, etc. formed on the junction surface of the first junction member M1 are recognized using the first imaging device 410 of the imaging device 400, recognition errors due to changes in the depth of focus may be reduced.

The shaft motor 30 is arranged on the upper side of the double-acting air bearing cylinder 10 in the Z-axis direction, and a weight of the cylinder rod 11 is canceled by the pressure control in the double-acting air bearing cylinder 10, so there is no need to for the shaft motor 30 to have load resistance. Accordingly, the shaft motor 30 may be used without changing its specifications when the maximum load of the double-acting air bearing cylinder 10 is increased. Therefore, a small shaft motor 30 may be used. Miniaturization of the shaft motor 30 enables the realization of a small and lightweight mechanism compared to cases where a large voice coil motor (VCM) or a linear motor is used as a drive motor, and it also suppresses the influence of temperature drift due to generation of heat, etc., contributing to high precision of position control, so it is extremely effective in the operation of the mounting device 1.

When the mounting device 1 moves the cylinder rod 11 over a long distance at a high speed, such as by first vertical moving amount, the position control response of the shaft motor 30 may be reduced to elevate and move the same by the servo valve 14. The shaft motor 30 does not interfere with the control of the servo valve 14 by delaying responsiveness. In addition, the mounting device 1 increases the control response of the shaft motor 30 when the position of the cylinder rod 11 enters a correction region, thereby controlling the same by the shaft motor 30. Accordingly, the mounting device 1 may determine the position of the cylinder rod 11 with high precision.

The flexible coupler 40 may connect the upper portion (near the upper side end) of the magnet rod 31 of the shaft motor 30 and the lower portion (near the lower side end) of the spline shaft 51 of the ball spline 50, and may maintain them. As shown in FIG. 2, the first maintaining portion or lower portion 41 disposed on the lower side of the flexible coupler 40 may maintain the upper portion of the magnet rod 31, and the second maintaining portion or upper portion 42 disposed on the upper side thereof may maintain the lower portion of the spline shaft 51. As the magnet rod 31 and the spline shaft 51 are connected through the flexible coupler 40, the influence of misalignment of eccentricity, etc. when the rotation from the piezo motor 70 is transmitted may be absorbed, and may not be transmitted to the double-acting air bearing cylinder 10. Accordingly, the bonding head 100 may prevent the double-acting air bearing cylinder 10 from being damaged.

The ball spline 50 may include a spline shaft 51, a spline nut 52, and an angular bearing 53. The upper portion (near the upper side end) of the spline nut 52 may be fixed to the rotor 60. An external circumferential surface of the spline nut 52, which serves as a bearing for the spline shaft 51, may be fixed to an inner race ring of the angular bearing 53, and an outer race ring of the angular bearing 53 may be fixed to the housing body 130 of the bonding head 100.

The spline shaft 51 may elevate and move along the Z-axis direction (vertical direction) inside the cylindrical spline nut 52, and may be rotatable with a long axis along the Z-axis of the cylinder rod 11 as the rotation axis. Accordingly, a torque of the rotor 60 rotated by the piezo motor 70 may be transmitted to the cylinder rod 11 from the spline shaft 51 through the flexible coupler 40, the magnet rod 31, and the rigid coupler 20. The spline shaft 51 may move in the Z-axis direction so the ball spline 50 may allow movement of the cylinder rod 11 in the Z-axis direction by the double-acting air bearing cylinder 10 or the shaft motor 30.

The rotor 60 may be fixed to the upper portion of the spline nut 52, may convert a driving force of the piezo motor 70 into the torque, and may transmit it to the spline nut 52. The rotor 60 may rotate in a predetermined direction with the long axis (or the center axis C) of the cylinder rod 11 as the rotation axis by the piezo motor 70.

The piezo motor 70 may be an actuator for rotating the rotor 60 in a predetermined direction by a predetermined angle (approximately ±5 degrees). Punching when the rotation direction stops may be reduced by using the contact type piezo motor 70 to the rotation of the cylinder rod 11.

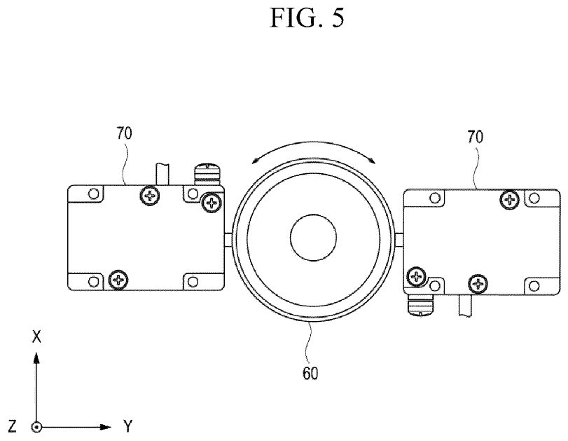

Two piezo motors 70, as shown in FIG. 5, may be installed in opposing positions with rotor 60 therebetween. Accordingly, the piezo motors 70 may support the rotor 60 from two directions, thereby increasing the holding power of the rotor 60 and reducing the load during rotation compared to a single motor. There is no limit to the installation number of the piezo motors 70, and it may be as few as one or as many as three or more.

The position detector 80 may have a first position detector 81 and a second position detector 82. The position detector 80 may detect current positions of the cylinder rod 11 in the vertical direction and rotation direction.

The first position detector 81 includes a first scale 81a and a first encoder sensor 81b. The first position detector 81 may decode a first encoder pattern P1 of the first scale 81a with the first encoder sensor 81b and may detect the position of the cylinder rod 11 in the vertical direction.

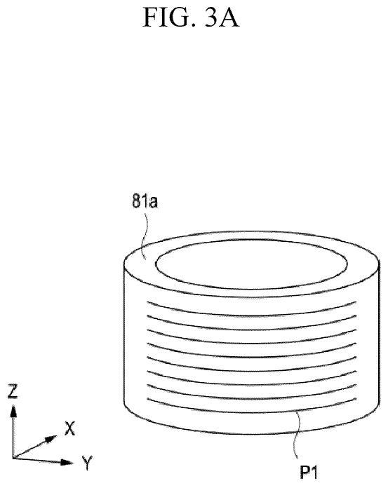

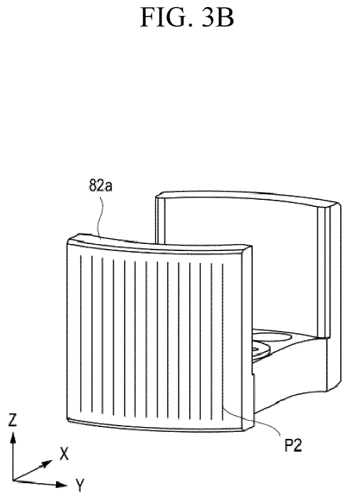

The first scale 81a may form a first encoder pattern P1 including a pattern sequence for detecting the position of the cylinder rod 11 in the vertical direction. The first encoder pattern P1 may, as shown in FIG. 3A, include a predetermined pattern sequence formed on the outer surface of the cylindrical member. This pattern sequence may be formed by arbitrarily combining patterns such as line patterns (line bodies by grooves, convex shapes, printing, etc.) and dot patterns. The first encoder pattern P1 may be formed in the detecting range of at least the first encoder sensor 81b. The first encoder sensor 81b may output pattern information deciphered from the first scale 81a as position information (vertical position information) of the current vertical direction of the cylinder rod 11 to the control device 500.

The first encoder pattern P1 may not be limited to the pattern form shown in FIG. 3A when the position of at least the cylinder rod 11 in the vertical direction is a pattern detectable by the first encoder sensor 81b. Also, the first encoder sensor 81b has no particular restrictions on the number of installations or installation positions when it may decipher the first encoder pattern P1 of the first scale 81a.

The first scale 81a may be integrally mounted on the external circumferential surface of the rigid coupler 20 to allow an operational range of the rotation directions of the cylinder rod 11. Accordingly, the first scale 81a is arranged coaxially with the cylinder rod 11 and is also arranged near the magnet rod 31 of the shaft motor 30 so it has the effect of suppressing generation of position control errors due to the shaft motor 30.

The second position detector 82 includes a second scale 82a and a second encoder sensor 82b. The second position detector 82 may decipher a second encoder pattern P2 of the second scale 82a with the second encoder sensor 82b and may detect the position of the cylinder rod 11 in the rotation direction.

The second scale 82a may form a second encoder pattern P2 including a pattern sequence for detecting the position of the cylinder rod 11 in the rotation direction. The second scale 82a may be arranged to oppose a base of the second scale 82a. The second encoder pattern P2 may, as shown in FIG. 3B, form a pattern sequence that is a combination of patterns. This pattern sequence may be formed by arbitrarily combining patterns such as line patterns (line bodies by grooves, convex shapes, printing, etc.) and dot patterns. The second encoder pattern P2 may be formed in the detecting range of at least the second encoder sensor 82b. The second encoder sensor 82b may output pattern information deciphered from the second scale 82a as position information (rotation position information) of the current rotation direction of the cylinder rod 11 to the control device 500.

A tab may be installed on a front end surface that corresponds to a lower portion of the cylinder rod 11, and the second scale 82a may be screw-fastened on the front end surface and may be fixed thereto. The second scale 82a may move in synchronization with the cylinder rod 11, allowing an operational range of the cylinder rod 11 in the vertical direction. The second scale 82a may be arranged near the head 120 for maintaining the first junction member M1 when installed on the lower portion of the cylinder rod 11, so that an Abbe error may be reduced and high precision of mounting precision may be achieved.

The second encoder pattern P2 may not be limited to the pattern shape shown in FIG. 3B when the position of the cylinder rod 11 in the rotation direction is at least the pattern detectable by the second encoder sensor 82b. In addition, the second encoder sensor 82b is not particularly limited in the number of installations or installation positions when it may decipher the second encoder pattern P2 of the second scale 82a.

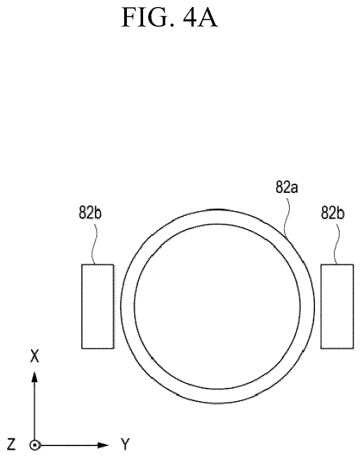

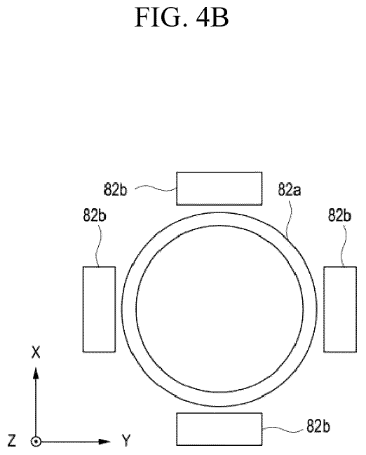

FIG. 4A and FIG. 4B show an arrangement of a scale and sensors of the second position detector 82. Referring to FIG. 4A, two second encoder sensors 82b may be arranged in the peripheral direction of the second scale 82a. The two second encoder sensor 82b of FIG. 4A may face each other with the second scale 82a therebetween. Referring to FIG. 4B, four second encoder sensors 82b may be arranged in the surrounding direction of the second scale 82a. Each one of the four second encoder sensors 82b of FIG. 4B may face another thereof with the second scale 82a therebetween.

As shown in FIG. 4A and FIG. 4B, regarding the second scale 82a, when the second encoder sensors 82b are arranged in pairs, it may be possible to detect the movement of the cylinder rod 11 in the horizontal direction. Accordingly, the mounting device 1 may correct a displacement of the cylinder rod 11 in the horizontal direction on the side of the bonding stage 300 by an alignment processing, and may further improve the component mounting precision. Referring to FIG. 4A and FIG. 4B, the second encoder pattern P2 (not shown) formed at the second scale 82a may be formed in the detecting range of the second encoder sensor 82b.

The mounting table 200 has a loader 210 for mounting the first junction member M1. The mounting table 200 may be configured to include a driving device for moving the loader 210 in the X-axis direction and the Y-axis direction to pick up the first junction members M1 mounted on the loader 210.

The bonding stage 300 maintains the second junction member M2 for bonding the first junction member M1. The second junction member M2 may mount the first junction member M1, such as a wafer, a chip, a die, or an interposer. Regarding the bonding stage 300, the second junction member M2 may be mounted on the stage 310. The stage 310 may be configured to move in the X-axis direction, the Y-axis direction, and the rotation direction with the Z-axis as a rotation axis by a driver 320. The driver 320 may correct the bonding position of the first junction member M1 by driving control of the control device 500.

The imaging device 400 may include a first imaging device 410 configured with a charge-coupled device (CCD) camera for photographing the junction surface of the first junction member M1 picked up from the mounting table 200, and a second imaging device 420 for photographing the bonding position of the second junction member M2. The imaging device 400 may photograph the junction surface of the first junction member M1 and the second junction member M2 under the control of the controller 510.

The first imaging device 410 may photograph the junction surface (alignment marks on the surface, etc.) of the first junction member M1 while the head 120 holds the first junction member M1. The first imaging device 410 may be installed at a position (or a first imaging position) where the first junction member M1 may be photographed between the mounting table 200 and the bonding stage 300. The first imaging device 410 may output photographed image data (first image data) to the control device 500.

The second imaging device 420 may be installed in conjunction with the bonding head 100 and may photograph the junction surface of the second junction member M2, which is the bonding position of the first junction member M1 before the first junction member M1 is bonded to the second junction member M2. The second imaging device 420 may output photographed image data (second image data) to the control device 500.

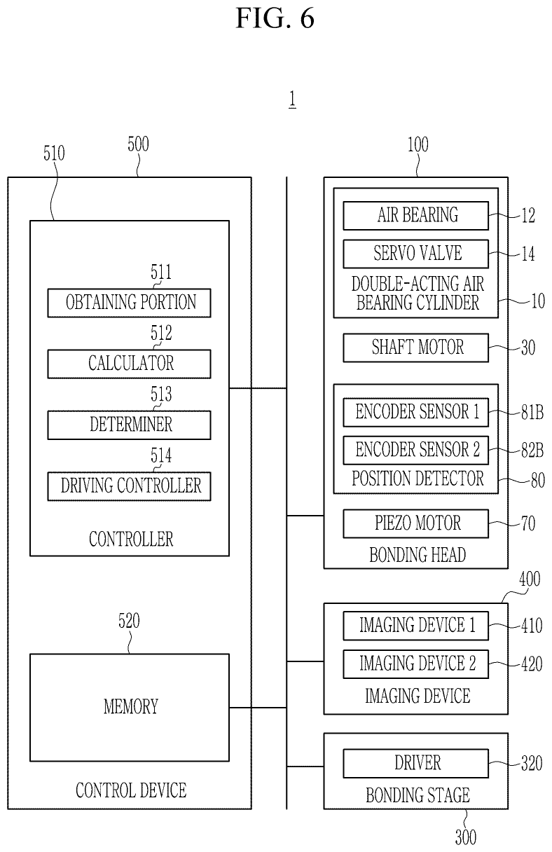

The control device 500 may, as shown in FIG. 6, include a controller 510 and a memory 520. The control device 500 may comprehensively perform various processes associated with the operation of the mounting device 1.

The controller 510 may be equipped with a CPU, RAM, ROM, etc., and may execute a control program, etc. to control parts of the mounting device 1 and process various operations. The controller 510 may execute control programs, etc. to function as the obtaining portion or module 511, the calculator 512, the determiner or determining module 513, and the driving controller 514.

The obtaining portion 511 may obtain the status of the respective parts of the mounting device 1, such as a moving status of the cylinder rod 11 and a driving status of the shaft motor 30. Additionally, the obtaining portion 511 may control the position detector 80 to obtain current position information (vertical position information and rotation position information) of the cylinder rod 11.

The calculator 512 may calculate the information required to control the parts of the mounting device 1. The calculator 512 may calculate the first vertical moving amount based on a predetermined target vertical position. The calculator 512 may calculate a position misalignment error of the target vertical position in the vertical direction (Z-axis direction) based on the predetermined target vertical position and the vertical position information detected after moving with the first vertical moving amount, and may calculate a second vertical moving amount according to the position misalignment error. The calculator 512 may calculate the position misalignment error of the target rotation position in the rotation direction based on the predetermined target rotation position and the rotation position information, and may calculate a rotation moving amount according to the position misalignment error. The calculator 512 may calculate an average thrust value of the shaft motor 30. The calculator 512 may calculate a position correction amount of the stage 310 for the bonding position of the first junction member M1 based on the second image data.

The calculator 512 may calculate the position misalignment amount (or a horizontal position misalignment amount) of the cylinder rod 11 in the horizontal direction when the second encoder sensors 82b are arranged as a configuration of the second position detector 82, as shown in FIG. 4A and FIG. 4B. The calculator 512 may calculate the corrected driving amount of the driver 320 of the bonding stage 300 based on the calculated horizontal position misalignment amount. The misalignment of the cylinder rod 11 in the horizontal direction may be compensated by correcting the position of the stage 310 of the bonding stage 300 based on the calculated corrected driving amount.

The determiner 513 may perform a determination process accompanying the control of the parts of the mounting device 1, and may execute the processes of the parts based on the determination result. The determiner 513 may determine whether the cylinder rod 11 has moved to the target vertical position based on the predetermined target vertical position and the vertical position information. The determiner 513 may determine whether the cylinder rod 11 has moved to the target rotation position based on a predetermined target rotation position and rotation position information. The determiner 513 may determine, based on the predetermined thrust determining threshold value and the average thrust value, whether the average thrust value exceeds the thrust determining threshold value.

The driving controller 514 may perform driving control of the parts configuring the mounting device 1. The driving controller 514 may control the driving device 110 to move the bonding head 100 to a predetermined position (a pickup position of the first junction member M1, a photographing position by the first imaging device 410, a photographing position by the second imaging device 420, a bonding position of the bonding stage 300, etc.). The driving controller 514 may control the driving of the first imaging device 410 to capture an image of the junction surface of the first junction member M1 picked up by the head 120. The driving controller 514 may drive and control the second imaging device 420 to capture an image of the junction surface of the second junction member M2, which becomes the bonding position of the first junction member M1. The driving controller 514 may drive and control the driver 320 of the bonding stage 300 to correct the bonding position of the first junction member M1 based on image data photographed by the imaging device 400.

The driving controller 514 may appropriately drive and control the double-acting air bearing cylinder 10, the shaft motor 30, and the piezo motor 70 to move (elevate and move, rotate) the cylinder rod 11 in a predetermined direction at a pickup position set for each first junction member M1, an imaging position of the first imaging device 410, and a bonding position for the second junction member M2.

The movement control of the cylinder rod 11 may be performed as follows. The driving controller 514 may drive and control the servo valve 14 based on the first vertical moving amount to move the cylinder rod 11 to the target vertical position. The driving controller 514 may drive and control the shaft motor 30 based on the second vertical moving amount to adjust and move the cylinder rod 11 to the target vertical position after moving by the first vertical moving amount. The driving controller 514 may drive and control the piezo motor 70 based on the rotation moving amount to move the cylinder rod 11 to the target rotation position. The driving controller 514 may control the double-acting air bearing cylinder 10 to raise the cylinder rod 11 to a predetermined position after pickup of the first junction member M1, photographing by the first imaging device 410, and bonding to the second junction member M2.

Regarding the descent control of the cylinder rod 11 of the driving controller 514, when the position of the cylinder rod 11 moved by the first vertical moving amount matches the target vertical position, it may become unnecessary to control the moving amount adjustment of the cylinder rod 11 in the second vertical moving amount. When the rotation position of the cylinder rod 11 matches the target rotation position, it may become unnecessary for the driving controller 514 to move and control the cylinder rod 11 in the rotation moving amount.

The driving controller 514 may control the opening of the servo valve 14 so that a load on the shaft motor 30 may not exceed the motor allowable value when the predetermined average thrust value exceeds a threshold value for determining the thrust while the shaft motor 30 is not driving. To suppress the load of the shaft motor 30, the weight of the cylinder rod 11 is canceled by the double-acting air bearing cylinder 10, but the shaft motor 30 is small so the load of the shaft motor 30 may increase due to a fluctuation in the supply pressure of several KPa, thereby exceeding the permissible value of the motor. In this regard, the mounting device 1 may perform the above-described control by the driving controller 514 so the increase of the load to the shaft motor 30 may be reduced. This processing is usually performed as a background processing during a descending control of the cylinder rod 11, but it may be applied during an ascending movement as well when a precise position determination is required during the ascending movement.

The memory 520 may include a ROM storing various programs or data in advance, a RAM temporarily storing programs or data as a work region, and a hard disk drive storing various programs or data. The memory 520 may store various types of information necessary for controlling the mounting device 1 in addition to the target vertical position, the target rotation position, and the threshold value for determining the thrust for each first junction member M1. The target vertical position or the target rotation position may be preset so that the head 120 of the cylinder rod 11 may have an appropriate position when lowering or rotating the cylinder rod 11 at each timing when picking up the first junction member M1, when capturing an image by the first imaging device 410, and when bonding the first junction member M1 to the second junction member M2.

A series of processing operations of the mounting device 1 will now be described.

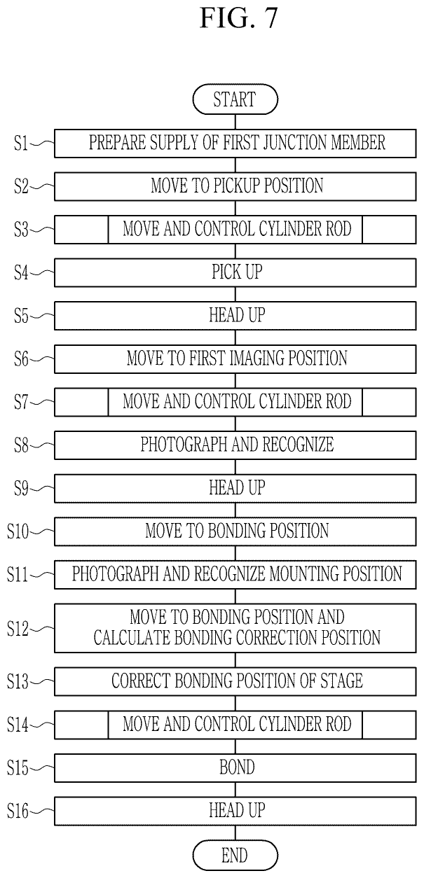

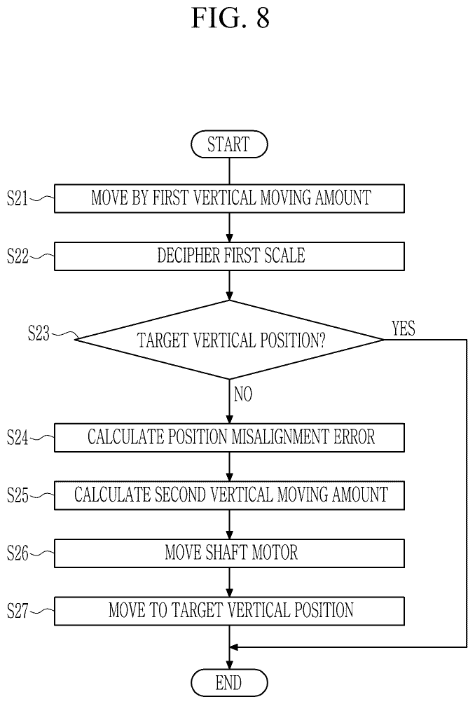

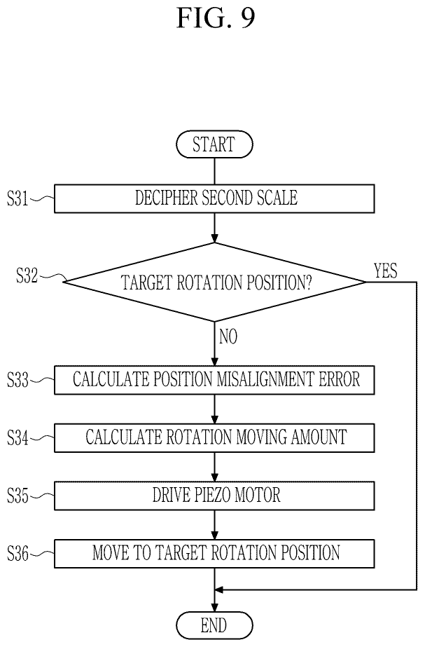

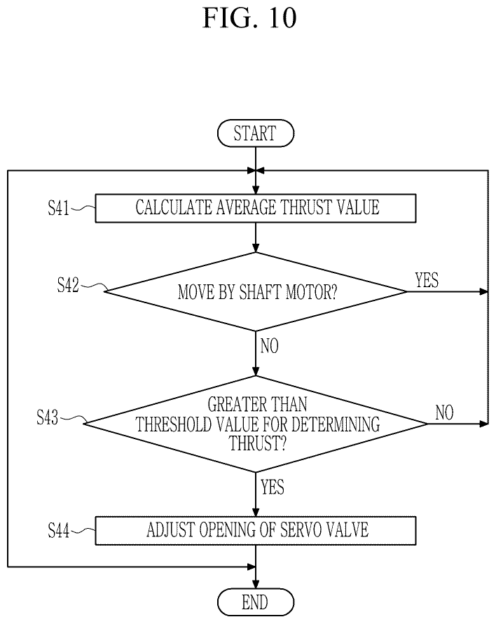

FIG. 7 shows a series of processing flows of the mounting device 1. FIG. 8 shows a processing flow on the movement (descending) of the cylinder rod 11 in the processing of the mounting device 1. FIG. 9 shows a processing flow on the movement (rotation) of the cylinder rod 11 in the processing of the mounting device 1. FIG. 10 shows a processing flow for reducing the load of the shaft motor 30 in the processing of the mounting device 1.

The mounting device 1 may, as shown in FIG. 7, prepare the first junction member M1 (S1). The mounting device 1 may move the bonding head 100 to the pickup position of the mounting table 200 (S2). The mounting device 1 may move the cylinder rod 11 to the pickup position and may then move and control the same (S3), may pick up the first junction member M1 (S4), and may then head up or move up the same (S5).

The mounting device 1 may move the bonding head 100 to the first imaging position (S6) and may move and control the cylinder rod 11 (S7). While the cylinder rod 11 is descended, the junction surface of the first junction member M1 may be photographed (S8), and may be headed up or moved up (S9).

The mounting device 1 may move up to the stage 310 of the bonding stage 300 (S10) and may photograph the junction surface of the second junction member M2 with the second imaging device 420 to recognize the bonding or mounting position (S11). Upon recognizing the bonding position, the bonding head 100 may be moved to the bonding position, and the position correction amount of the stage 310 for the bonding position of the first junction member M1 may be calculated (S12). The mounting device 1 may perform position correction of the stage 310 based on the calculated position correction amount (S13).

The mounting device 1 may move and control the cylinder rod 11 (S14), may bond the first junction member M1 to the bonding position of the second junction member M2 (S15), and may head up or move up the same (S16). By the above, the process for bonding the mounting device 1 is completed.

The movement and control of the cylinder rod 11 during descending will now be described. The process shown in FIG. 8 may be executed when correcting the vertical position of the cylinder rod 11 at S3, S7, and S14 (FIG. 7).

As shown in FIG. 8, the mounting device 1 may move the cylinder rod 11 by the first vertical moving amount (S21). On moving the cylinder rod 11 by the first vertical moving amount, the first scale 81a may be deciphered by the first encoder sensor 81b to obtain the current vertical position information of the cylinder rod 11 (S22).

The mounting device 1 may compare the deciphered vertical position information and the target vertical position to determine whether the cylinder rod 11 has moved to the target vertical position (S23).

At S23, if the cylinder rod 11 has moved to the target vertical position (S23—Yes), the process ends. If the cylinder rod 11 has not moved to the target vertical position (S23—No), the position misalignment error for the target vertical position may be calculated (S24), and the second vertical moving amount for the position misalignment error may be calculated (S25).

The mounting device 1 may drive the motor 30 with the calculated second vertical moving amount (S26), may adjust and move the cylinder rod 11 to the target vertical position (S27), and may terminate the process.

Movement and control of the cylinder rod 11 during rotation will now be described. The process shown in FIG. 9 may be appropriately executed when correcting the rotation position of the cylinder rod 11 at S3, S7, and S14 (FIG. 7).

As shown in FIG. 9, the mounting device 1 may obtain current rotation position information of the cylinder rod 11 by deciphering the second scale 82a with the second encoder sensor 82b (S31). The mounting device 1 may compare the deciphered rotation position information and the target rotation position to determine whether the cylinder rod 11 is at the target rotation position (S32).

At S32, if the cylinder rod 11 is at the target rotation position (S32—Yes), the process ends. If the cylinder rod 11 is not at the target rotation position (S32—No), the position misalignment error for the target rotation position may be calculated (S33), and the rotation moving amount for the position misalignment error may be calculated (S34).

The mounting device 1 may drive the piezo motor 70 with the calculated rotation moving amount (S35) and may move the cylinder rod 11 to the target rotation position (S36), and may end the process.

Regarding the processing of S3, S7, and S14 of FIG. 7, an execution order of the movement and control during the descent in the vertical direction shown in FIG. 8 and the movement and control during rotation shown in FIG. 9 may not be particularly limited, and the rotation and movement may be performed after the descending and movement, and the descending and movement may be performed after the rotation and movement.

Processing and control for reducing the load on the shaft motor 30 will now be described. The processing shown in FIG. 10 may be executed as a background processing during the descending and control of the cylinder rod 11 shown in FIG. 9 to ensure that the load on the shaft motor 30 does not exceed the motor allowable value.

As shown in FIG. 10, the mounting device 1 may calculate the average thrust value of the shaft motor 30 (S41). The mounting device 1 may determine whether the cylinder rod 11 is being moved by the shaft motor 30 (S42).

At S42, if the cylinder rod 11 is moving by the shaft motor 30 (S42—Yes), it returns to S41. If the cylinder rod 11 is not moved by the shaft motor 30 (S42—No), the predetermined threshold value for determining a thrust is compared with the average thrust value to determine whether the average thrust value exceeds the threshold value for determining a thrust (S43).

At S43, if the average thrust value exceeds the threshold value for determining a thrust (S43—Yes), the opening of the servo valve 14 may be adjusted so that the average thrust value may not exceed the threshold value for determining a thrust (S44), and it returns to S41. If the average thrust value does not exceed the threshold value for determining a thrust (S43—No), it returns to S41. The processing flow shown in FIG. 10 may be constantly executed while the mounting device 1 is operated, and may end when the mounting process is stopped due to maintenance of the mounting device 1, etc.

As described above, the mounting device 1 according to the present disclosure may include a bonding head 100 and a bonding stage 300.

The bonding head 100 may include: a double-acting air bearing cylinder 10 having a cylinder rod 11 extending in the vertical direction and moving the cylinder rod 11 in the vertical direction by the first vertical moving amount; a first scale 81a arranged on the same axis as the cylinder rod 11 to allow the operational range of the cylinder rod 11 in the rotation direction, and having a first encoder pattern P1 formed of a pattern sequence for detecting the position of the cylinder rod 11 in the vertical direction; a first encoder sensor 81b arranged on a position facing the first scale 81a and deciphering the position of the first encoder pattern P1; a second scale 82a arranged on the same axis as the cylinder rod 11 to allow the operational range of the cylinder rod 11 in the vertical direction, and having a second encoder pattern P2 formed of a pattern sequence for detecting the position of the cylinder rod 11 in the rotation direction; a second encoder sensor 82b arranged on a position facing the second scale 82a and deciphering the position of the second encoder pattern P2; a shaft motor 30 for moving the position of the cylinder rod 11 in the vertical direction by the second vertical moving amount when correcting the vertical position so that the position of the cylinder rod 11 in the vertical direction may become the target vertical position based on the deciphering result of the first encoder sensor 81b; and a piezo motor 70 arranged on the same axis as the cylinder rod 11 and moving the position of the cylinder rod 11 in the rotation direction by the rotation moving amount so that the rotation position of the cylinder rod 11 may be the target rotation position based on the deciphering result of the second encoder sensor 82b.

With this configuration, the mounting device 1 may move the cylinder rod 11 to the double-acting air bearing cylinder 10 by the first vertical moving amount, and may then drive the shaft motor 30 to adjust the same by the second vertical moving amount when correcting the vertical position so that it may become the target vertical position. Accordingly, the mounting device 1 may increase the position control performance of the cylinder rod 11, thereby realizing high-precision bonding. It may be possible to reduce the recognition errors due to changes in the depth of focus when the first imaging device 410 recognizes alignment marks, etc. of the junction surface of the first junction member M1 from the lower portion of the head 120. As the first scale 81a for allowing the operational range in the rotation direction and the second scale 82a for allowing the operational range in the vertical direction are arranged on the same axis as the cylinder rod 11, the mounting device 1 may perform a high-precision position control of the cylinder rod 11 in the vertical direction and the rotation direction.

While example embodiments of the present disclosure have been particularly shown and described, it will be understood by one of ordinary skill in the art that variations in form and detail may be made therein without departing from the spirit and scope of the attached claims.

What is claimed is:

1. A mounting device including a bonding head and a bonding stage,
wherein the bonding head includes:
a double-acting air bearing cylinder having a cylinder rod extending in a vertical direction and configured to move the cylinder rod in the vertical direction by a first vertical moving amount,
a position detector including a first position detector configured to detect a position of the cylinder rod in the vertical direction and a second position detector configured to detect a rotation position of the cylinder rod in a rotation direction,
a shaft motor arranged on a same axis as the cylinder rod, and configured to move the position of the cylinder rod in the vertical direction by a second vertical moving amount so that the position of the cylinder rod in the vertical direction detected from the first position detector becomes a target vertical position, and
a piezo motor configured to move the cylinder rod in the rotation direction by a rotation moving amount so that the rotation position of the cylinder rod detected from the second position detector becomes a target rotation position.

2. The mounting device of claim 1, wherein
the first position detector includes:
a first scale arranged on the same axis as the cylinder rod to allow an operational range of the cylinder rod in the rotation direction and having a first encoder pattern including a pattern sequence for detecting the position of the cylinder rod in the vertical direction, and
a first encoder sensor facing the first scale and configured to decipher a position of the first encoder pattern.

3. The mounting device of claim 2, wherein
the second position detector includes:
a second scale arranged on the same axis as the cylinder rod to allow the operational range of the cylinder rod in the vertical direction and having a second encoder pattern including a pattern sequence for detecting the position of the cylinder rod in the rotation direction, and
a second encoder sensor facing the second scale and configured to decipher a position of the second encoder pattern.

4. The mounting device of claim 3, wherein
the second scale is at a lower portion of the cylinder rod of the double-acting air bearing cylinder.

5. The mounting device of claim 1, wherein
the double-acting air bearing cylinder is below the shaft motor.

6. The mounting device of claim 1, wherein
the mounting device includes:
a ball spline including a spline shaft, a spline nut, and an angular bearing including an outer race ring fixed to a housing of the bonding head and an inner ring race ring fixed to the spline nut, and arranged above the shaft motor and configured to transmit a driving force of the piezo motor,
a flexible coupler connecting a lower portion of the spline shaft and an upper portion of a magnet rod of the shaft motor in a synchronously rotatable manner,
a rigid coupler connecting a lower portion of the magnet rod of the shaft motor and an upper portion of the cylinder rod of the double-acting air bearing cylinder in a synchronously rotatable manner, and
a rotor fixed to the spline nut, and configured to convert the driving force of the piezo motor into a torque and transmit the same to the spline nut.

7. The mounting device of claim 3, wherein
the second encoder sensor includes a plurality of second encoder sensors that are arranged around the second scale, and that are configured to detect position misalignment of a rod end of the double-acting air bearing cylinder in a horizontal direction.

8. The mounting device of claim 1, wherein
the double-acting air bearing cylinder includes a servo valve configured to adjust inflow/outflow amounts of air to/from the cylinder so that the cylinder rod moves by the first vertical moving amount.

9. The mounting device of claim 8, wherein
the mounting device includes a control device including:
a calculator configured to calculate an average thrust value of the shaft motor,
an obtaining module configured to obtain a driving state of the shaft motor,
a determining module configured to compare the average thrust value calculated by the calculator and a predetermined threshold value to determine whether the average thrust value exceeds the threshold value, and
a driving controller configured to adjust opening of the servo valve of the double-acting air bearing cylinder so that a load of the shaft motor does not exceed an allowable value based on a determination result of the determining module.

10. The mounting device of claim 1, wherein
the bonding head is configured to adsorb a first junction member and move in a horizontal direction,
the bonding stage includes a stage configured to support a second junction member on which the first junction member is mounted, and
the stage is rotatable and moveable with at least one of three axes that is vertical as a rotation axis.

11. A mounting device including a bonding head and a bonding stage,
wherein the bonding head includes:
a double-acting air bearing cylinder having a cylinder rod extending in a vertical direction and configured to move the cylinder rod in the vertical direction by a first vertical moving amount,
a first scale arranged on the same axis as the cylinder rod to allow an operational range of the cylinder rod in a rotation direction, and having a first encoder pattern including a pattern sequence for detecting a position of the cylinder rod in the vertical direction,
a first encoder sensor facing the first scale, and configured to decipher a position of the first encoder pattern,
a second scale arranged on a same axis as the cylinder rod to allow the operational range of the cylinder rod in the vertical direction, and having a second encoder pattern including a pattern sequence for detecting a rotation position of the cylinder rod in the rotation direction,
a second encoder sensor facing the second scale, and configured to decipher a position of the second encoder pattern,
a shaft motor arranged on the same axis as the cylinder rod, and configured to move the position of the cylinder rod in the vertical direction by a second vertical moving amount when correcting a vertical position so that the position of the cylinder rod in the vertical direction becomes a target vertical position based on a deciphering result of the first encoder sensor, and
a piezo motor configured to move the cylinder rod in a rotation direction by a rotation moving amount so that the rotation position of the cylinder rod becomes a target rotation position based on a deciphering result of the second encoder sensor.

12. The mounting device of claim 11, wherein
the second scale is at a lower portion of the cylinder rod of the double-acting air bearing cylinder.

13. The mounting device of claim 11, wherein
the double-acting air bearing cylinder is arranged below the shaft motor.

14. The mounting device of claim 11, wherein
the mounting device includes:
a ball spline including a spline shaft, a spline nut, and an angular bearing including an outer race ring fixed to a housing of the bonding head and an inner ring race ring fixed to the spline nut, and arranged above the shaft motor and configured to transmit a driving force of the piezo motor,
a flexible coupler connecting a lower portion of the spline shaft and an upper portion of a magnet rod of the shaft motor in a synchronously rotatable manner,
a rigid coupler connecting a lower portion of the magnet rod of the shaft motor and an upper portion of the cylinder rod of the double-acting air bearing cylinder in a synchronously rotatable manner, and
a rotor fixed to the spline nut, and configured to convert the driving force of the piezo motor into a torque and transmit the same to the spline nut.

15. The mounting device of claim 11, wherein
the second encoder sensor includes a plurality of second encoder sensors that are arranged around the second scale, and are configured to detect position misalignment of a rod end of the double-acting air bearing cylinder in a horizontal direction.

16. The mounting device of claim 11, wherein
the double-acting air bearing cylinder includes a servo valve configured to adjust inflow/outflow amounts of air to/from the cylinder so that the cylinder rod moves by the first vertical moving amount.

17. The mounting device of claim 16, wherein
the mounting device includes a control device including:
a calculator configured to calculate an average thrust value of the shaft motor,
an obtaining portion configured to obtain a driving state of the shaft motor,
a determiner configured to compare the average thrust value calculated by the calculator and a predetermined threshold value to determine whether the average thrust value exceeds the threshold value, and
a driving controller configured to adjust opening of the servo valve of the double-acting air bearing cylinder so that a load of the shaft motor does not exceed an allowable value based on a determination result of the determiner.

18. The mounting device of claim 11, wherein
the bonding head is configured to adsorb a first junction member and move in a horizontal direction,
the bonding stage includes a stage configured to support a second junction member on which the first junction member is mounted, and
the stage is rotatable and moveable with at least one of three axes that is vertical as a rotation axis.

19. The mounting device of claim 18, further comprising
an imaging device including a CCD camera, and configured to obtain image data a junction surface of the first junction member and a junction surface of the second junction member,
wherein the imaging device controls driving of the stage based on the image data.

20. A mounting device comprising:
a bonding head configured to adsorb a first junction member and move in a horizontal direction;
a bonding stage configured to support a second junction member on which the first junction member is mounted, and including a stage rotatable and moveable with at least one of three axes that is vertical as a rotation axis;
an imaging device including a CCD camera configured to obtain image data of a junction surface of the first junction member and a junction surface of the second junction member; and
a control device configured to control movement of the bonding head, movement of the stage, and driving of the imaging device,
wherein the bonding head includes:
a double-acting air bearing cylinder having a cylinder rod extending in a vertical direction, and configured to move the cylinder rod in the vertical direction by a first vertical moving amount,
a first scale arranged on the same axis as the cylinder rod to allow an operational range of the cylinder rod in a rotation direction and having a first encoder pattern including a pattern sequence for detecting a position of the cylinder rod in the vertical direction,
a first encoder sensor facing the first scale and configured to decipher a position of the first encoder pattern,
a second scale arranged on the same axis as the cylinder rod to allow the operational range of the cylinder rod in the vertical direction and having a second encoder pattern including a pattern sequence for detecting the position of the cylinder rod in the rotation direction,
a second encoder sensor facing the second scale and configured to decipher a position of the second encoder pattern,
a shaft motor arranged on the same axis as the cylinder rod, and configured to move the position of the cylinder rod in the vertical direction by a second vertical moving amount when correcting a vertical position so that the position of the cylinder rod in the vertical direction becomes a target vertical position based on a deciphering result of the first encoder sensor, and
a piezo motor configured to move the cylinder rod in the rotation direction by a rotation moving amount so that a rotation position of the cylinder rod becomes a target rotation position based on a deciphering result of the second encoder sensor.
